(19) United States
(12) Patent Application Publication
(10) Pub. No.: US 2023/0249438 A1
(43) Pub. Date: Aug. 10, 2023

(54) METAL CLAD SUBSTRATE

(71) Applicant: Polytronics Technology Corp., Hsinchu (TW)

(72) Inventors: KAI-WEI LO, Zhubei City (TW); KUO-HSUN CHEN, Toufen City (TW); HSIANG-YUN YANG, Zhudong Township (TW); CHAO-JEN WANG, Tainan City (TW)

(21) Appl. No.: 17/731,181

(22) Filed: Apr. 27, 2022

(30) Foreign Application Priority Data
Feb. 9, 2022 (TW) 111104754

(51) Int. Cl. B32B 15/01; B32B 37/12; C09J 9/00; C08K 3/40; C09J 163/00; B32B 15/04; B32B 15/20

(52) U.S. Cl. CPC B32B 15/017; B32B 15/20; B32B 15/043; B32B 37/12; C08K 3/40; C09J 9/00; C09J 163/00; C08K 2003/2227; C08K 2201/001

(57) ABSTRACT

A metal clad substrate is disclosed. The metal clad substrate includes a metal baseplate, a metal layer, and a thermally conductive bonding layer disposed therebetween. The thermally conductive bonding layer includes a lower adhesive layer, a fiber-containing layer, and an upper adhesive layer. An upper side and a lower side of the upper adhesive layer contacts the metal layer and the fiber-containing layer, respectively. An upper side and a lower side of the lower adhesive layer contacts the fiber-containing layer and the metal baseplate, respectively. Each of the metal layer and the metal baseplate has a thickness of 0.3 mm - 15 mm. The fiber-containing layer includes a polymer as well as a heat conductive filler and a short fiber evenly dispersed in the polymer. The short fiber is in shape of a string and has a length of 5 µm-210 µm.

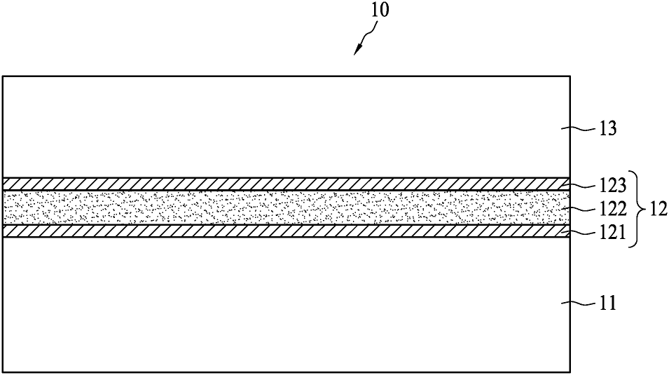

### BACKGROUND OF THE INVENTION

### Field of the Invention

The present application relates to a metal clad substrate insulated metal substrate, and more specifically, to a metal clad substrate suitable for high power or large current applications using thick copper circuit.

### Description of the Related Art

With advancement of technology, it would be required and becomes a trend that electronic devices input and/or output high power or large currents in the near future, such as those applications in electric vehicle, Internet of Things (IoT)or high-speed arithmetic. Therefore, the metal circuit on top of circuit board should have a thicker thickness than before in order to accommodate high power or large currents, wherein the so-called “metal circuit” is generally made of copper, and the copper circuit has a thickness greater than before and thus called “thick copper circuit” that has a thickness of at least of 0.2 mm. In applications with high power or large currents, the circuit board having electronic devices electrically attached thereon will generate a large amount of heat that accumulates gradually, and the electronic devices by itself will generate a large amount of heat as well, therefore this force the circuit board to have an excellent heat dissipation efficiency when compared to traditional circuit board. Use of a thick copper circuit could not only make circuit accommodate higher power and larger currents but facilitate heat conduction along horizontal direction and vertical direction within the circuit. Specifically, for a circuit board having a thick copper circuit, heat could be conducted firstly along horizontal direction in the circuit, and then be conducted upwards within the circuit and ultimately be dissipated into upper external environment. Alternatively, after heat is conducted firstly along horizontal direction in the circuit having a thick thickness, heat is thereafter conducted downwards via a thermally conductive insulation layer of the circuit board to a bottom metal base (or heat sink element) and is finally dissipated into lower external environment. Because there are the two heat transfer paths for a circuit board having a thick copper circuit where heat can be dissipated, the circuit board having a thick copper circuit has an excellent heat dissipation efficiency when compared to traditional circuit board. Accordingly, there is no doubt that it is a trend that the circuit board has a thick copper circuit.

Traditionally, a commonly used circuit board could be manufactured from an insulated metal substrate (IMS) or a directed bonded copper (DBC) ceramic substrate by performing exposure, development and etching steps on top copper foil of substrate to make the copper foil become metal circuit. However, either IMS or DBC substrate is not suitably used for forming a circuit board having a thick copper circuit because theses substrates will encounter some problems detailed below.

A DBC substrate is a thermally conductive substrate which includes a ceramic layer with an upper copper foil attached to top of the ceramic layer and a lower copper foil attached to bottom of the ceramic layer. If the thickness of the upper copper foil of DBC substrate is intended to be increased to 0.2 mm, or even at least 0.3 mm, for applications using thick copper circuit, it is very likely that, at high temperature, separation or delamination between the copper foil and the ceramic layer occurs because the copper foil and the ceramic layer differs significantly in coefficient of thermal expansion (CTE) from each other. Although, in order to solve this problem, there have been some manufacturers drilling holes through the ceramic layer to release thermal stress at high temperature between the copper foil and the ceramic layer, ceramic is a material that is very rigid and brittle, and thus the ceramic layer may easily crack during drilling process. Apparently, traditional DBC substrate cannot be used for applications using thick copper circuit.

An IMS is a thermally conductive substrate using polymer as a matrix material in a thermally conductive and electrically insulation layer of the IMS, wherein a large amount of heat conductive fillers is evenly dispersed in the polymer. A copper coil and a metal plate (e.g., a copper plate or an aluminum plate) are coupled to upper and lower surfaces of the thermally conductive and electrically insulation layer, respectively, to form a thermally conductive substrate having a sandwiched structure. If the thickness of upper copper foil of IMS is intended to be increased to 0.2 mm or 0.3 mm, the circuit board manufactured from IMS could endure high power or large currents. However, for applications using thick copper circuit, a large amount of heat generated by large currents in the circuit board will make volume resistivity of the thermally conductive and electrically insulation layer drops drastically at high temperature. Certainly, the volume resistivity of IMS will drop drastically at high temperature as well. For example, a ratio of volume resistivity of the thermally conductive and electrically insulation layer at 175° C. to volume resistivity of the thermally conductive and electrically insulation layer at 25° C. is smaller than 10⁻³. This is an inherent property of the thermally conductive and electrically insulation layer of IMS. For this reason, it can be predicted that voltage endurance of the circuit board will decrease with increase of temperature. Therefore, in practice, the circuit board made from IMS cannot endure high voltage if it is used in the future. Even, the copper foil and the metal plate may be electrically connected to each other via the thermally conductive and electrically insulation layer as IMS is operated at high temperature, where such a case is called “dielectric breakdown”. Therefore, traditional IMS thermally conductive substrate cannot be used for applications using thick copper circuit as well.

In addition to IMS and DBC substrate, copper clad laminate (CCL) is an another kind of raw material for manufacturing a printed circuit board. CCL has a laminate structure by hot-pressing a prepreg (which is formed by impregnating a fiber glass cloth with resin) and a copper coil at high temperature and high pressure. The fiber glass cloth is used to increase structural strength of CCL, and thus the fiber glass cloth has to have a very thick thickness and is distributed over entire area of CCL. But, it is well-known that the fiber glass cloth has a very low heat conductivity. Thus, such a structure design makes CCL have a quite poor heat dissipation efficiency. In particular, the heat conductivity of CCL is less then one tenth of that of IMS or DBC substrate. CCL is also not a substrate suitable for applications using thick copper circuit.

Accordingly, there is a need to provide a solution to the above-said problems, where traditional thermally conductive substrate encounters problems including delamination, dielectric breakdown, and/or poor heat dissipation efficiency.

### SUMMARY OF THE INVENTION

To solve aforementioned problems, the present invention provides a metal clad substrate. The metal clad substrate has a strong bonding strength between layers, a superior heat conductivity, a good resistance at high temperature of 150° C., and a good resistance recovery, therefore the metal clad substrate of the present invention is particularly suitable for high power or large current applications using thick copper circuit.

The present application provides a metal clad substrate. The metal clad substrate includes a metal baseplate, a metal layer, and a thermally conductive bonding layer disposed therebetween. The thermally conductive bonding layer includes a lower adhesive layer, a fiber-containing layer, and an upper adhesive layer from bottom to top. An upper side and a lower side of the upper adhesive layer contacts the metal layer and the fiber-containing layer, respectively. An upper side and a lower side of the lower adhesive layer contacts the fiber-containing layer and the metal baseplate, respectively. Each of the metal layer and the metal baseplate has a thickness of 0.3 mm - 15 mm. The fiber-containing layer includes a polymer, and further includes a heat conductive filler and a short fiber both evenly dispersed in the polymer. The short fiber is in shape of a string and has a length of 5 µm-210 µm.

In an embodiment, the metal layer is a copper layer, and the metal baseplate is a copper baseplate or an aluminum baseplate.

In an embodiment, the short fiber is selected from the group consisting of short glass fiber, calcium silicate fiber, aluminum silicate fiber, carbon fiber, gypsum fiber, and any mixtures thereof.

In an embodiment, the short fiber has a length shorter than a thickness of the fiber-containing layer.

In an embodiment, a length of the short fiber is in the range of 5 µm-80 µm.

In an embodiment, the polymer comprises 10%-30% by weight of the fiber-containing layer and includes thermoset epoxy resin, the heat conductive fillers comprise 65%-85% by weight of the fiber-containing layer, and the short fiber comprises 3%-10% by weight of the fiber-containing layer; and wherein the fiber-containing layer has a thickness ranging from 50 µm to 210 µm, and the fiber-containing layer has a heat conductivity between 2 W/m·K and 15 W/m·K.

In an embodiment, the heat conductive filler comprises one or more ceramic powders that is selected from nitride, oxide, or the mixture thereof; wherein the nitride is selected from the group consisting of zirconium nitride, boron nitride, aluminum nitride, and silicon nitride; and wherein the oxide is selected from the group consisting of aluminum oxide, magnesium oxide, zinc oxide, silicon dioxide, and titanium dioxide.

In an embodiment, both the upper adhesive layer and the lower adhesive layer are made from an adhesive material, the adhesive material comprising:
a polymeric component comprising 10%-30% by weight of the adhesive material, and comprising thermoset epoxy resin and thermoplastic configured to improve impact resistance of the thermoset epoxy resin; and
a heat conductive filler evenly dispersed in the polymeric component, and comprising 70%-90% by weight of the adhesive material;
wherein the adhesive material has a heat conductivity between 2 W/m·K and 15 W/m·K.

In an embodiment, the heat conductive filler comprises one or more ceramic powders that is selected from nitride, oxide, or the mixture thereof; wherein the nitride is selected from the group consisting of zirconium nitride, boron nitride, aluminum nitride, and silicon nitride; and wherein the oxide is selected from the group consisting of aluminum oxide, magnesium oxide, zinc oxide, silicon dioxide, and titanium dioxide.

In an embodiment, a bonding strength between the thermally conductive bonding layer and the metal layer as well as a bonding strength between the thermally conductive bonding layer and the metal baseplate ranges from 0.8 Kg/cm to 3.0 Kg/cm.

In an embodiment, each of a thickness of the upper adhesive layer and a thickness of the lower adhesive layer falls within the range of 30 µm-150 µm.

In an embodiment, a resistance of the metal clad substrate at 150° C. is greater than 1×10¹⁰ Ω.

In an embodiment, after a thermal shock test is conducted on the metal clad substrate in an environment of -40° C. followed by 150° C. for 500 cycles, a resistance of the metal clad substrate at 25° C. is greater than 1×10¹¹ Ω.

In an embodiment, a glass transition temperature Tg of the thermally conductive bonding layer is in the range of 120° C.-380° C.

According to the present invention, a metal clad substrate is disclosed. The metal clad substrate has a strong bonding strength between layers, a superior heat conductivity, a good resistance at high temperature of 150° C., and a good resistance recovery, therefore the metal clad substrate of the present invention is particularly suitable for high power or large current applications using thick copper circuit, thus providing a solution to the traditional thermally conductive substrate which encounters the problems as described above.

### BRIEF DESCRIPTION OF THE DRAWINGS

The present application will be described according to the appended drawings in which:

The FIGURE shows a cross-sectional view of a metal clad substrate in accordance with an embodiment of the present invention.

### DETAILED DESCRIPTION OF THE INVENTION

The making and using of the presently preferred illustrative embodiments are discussed in detail below. It should be appreciated, however, that the present application provides many applicable inventive concepts that can be embodied in a wide variety of specific contexts. The specific illustrative embodiments discussed are merely illustrative of specific ways to make and use the invention, and do not limit the scope of the invention.

The Figure shows a cross-sectional view of a metal clad substrate 10 in accordance with an embodiment of the present invention. The metal clad substrate 10 generally is in shape of a plate. The metal clad substrate 10 includes a metal baseplate 11, a metal layer 13, and a thermally conductive bonding layer 12. The thermally conductive bonding layer 12 is disposed between the metal baseplate 11 and the metal layer 13.

The thermally conductive bonding layer 12 includes a lower adhesive layer 121, a fiber-containing layer 122, and an upper adhesive layer 123 from bottom to top. An upper side and a lower side of the upper adhesive layer 123 contacts the metal layer 13 and the fiber-containing layer 122, respectively. An upper side and a lower side of the lower adhesive layer 121 contacts the fiber-containing layer 122 and the metal baseplate 11, respectively. Both the upper adhesive layer 123 and the lower adhesive layer 121 includes a polymer and a large amount of heat conductive fillers evenly dispersed in the polymer, and therefore it is suitable for them in use for bonding metal components. The metal components may comprise copper, aluminum, nickel, iron, tin, gold, silver or alloy thereof. After the metal baseplate 11, the lower adhesive layer 121, the fiber-containing layer 122, the upper adhesive layer 123 and the metal layer 13 are arranged and/or disposed from bottom to top, they may be hot-pressed to form a cured laminate structure.

Any patterning technique (such as exposure, development and etching steps, or Computer Numerical Control (CNC)) may be used to remove a portion of the metal layer, thus forming metal circuit, and thus a circuit board having an excellent heat dissipation efficiency is produced. It should be noted that each of the metal layer 13 and the metal baseplate 11 should have a thick thickness to an extent in order to generate such a function of excellent heat dissipation efficiency, thereby the metal clad substrate 10 could be used in applications requiring high power or large currents. Heat, which is generated by the electronic devices electrically attached onto the circuit, in the circuit board could be conducted upwards into upper external environment via the metal circuit, or could be conducted downwards via the thermally conductive bonding layer 12 to the metal baseplate 11 and further be dissipated into lower external environment, such that heat can be efficiently dissipated according to the present invention. In thick copper circuit applications, each of the metal layer 13 and the metal baseplate 11 has a thickness of 0.3 mm -15 mm, such as 0.5 mm, 1 mm, 3 mm, 5 mm, 7 mm, 9 mm, 11 mm or 13 mm. In an embodiment, the metal baseplate 11 could be a copper baseplate or an aluminum baseplate, and the metal layer 13 could be a copper layer. In a preferred embodiment, the metal baseplate 11 has a thickness of at least 0.5 mm. Because the metal baseplate 11 has such a thick thickness greater than 0.5 mm, Computer Numerical Control (CNC) may be used with a rotary cutter to remove a portion of the metal layer 13, such that a metallic heat dissipation element having a plurality heat dissipating fins or a plurality of thermally conductive pillars is thus formed. If the circuit board formed in this way is used for thick copper circuit applications, it is preferred that a thickness of metal layer 13 is greater than at least 0.2 mm.

The fiber-containing layer 122 is disposed between the upper adhesive layer 123 and the lower adhesive layer 121, and contacts the upper adhesive layer 123 and the lower adhesive layer 121. According to the present invention, the fiber-containing layer 122 has a thickness of 50 µm-210µm, such as 70 µm, 90 µm, 110 µm, 130 µm, 150 µm, 170 µm or 190 µm, and preferably falling within the range of 80 µm-110µm. The fiber-containing layer 122 includes a polymer as well as a large amount of heat conductive fillers and a short fiber, wherein both the heat conductive fillers and the short fiber are evenly dispersed in the polymer. The fiber-containing layer 122 includes a polymer as well as a heat conductive filler and a short fiber, wherein both the heat conductive filler and the short fiber are evenly dispersed in the polymer. In an embodiment, the polymer comprises thermoset epoxy resin, and a thermoplastic may be mixed with thermoset epoxy resin to enhance adhesive strength between the fiber-containing layer 122 and the upper adhesive layer 123 and to enhance adhesive strength between the fiber-containing layer 122 and the lower adhesive layer 121. In an embodiment, the polymer comprises 10%-30% (e.g., 15%, 20% or 25%) by weight of the fiber-containing layer 122; the heat conductive fillers comprise 65%-85% (e.g., 70%, 75% or 80%) by weight of the fiber-containing layer 122; and the short fiber comprises 3%-10% (e.g., 4%, 5%, 6%, 7%, 8% or 9%) by weight of the fiber-containing layer 122. The heat conductive filler may comprise one or more ceramic powders that can be selected from nitride, oxide, or the mixture thereof. The nitride can be selected from the group consisting essentially of zirconium nitride, boron nitride, aluminum nitride, and silicon nitride. The oxide can be selected from the group consisting essentially of aluminum oxide, magnesium oxide, zinc oxide, silicon dioxide and titanium dioxide. The composition of the fiber-containing layer 122 is prepared and adjusted to make the fiber-containing layer 122 have a heat conductivity between 2 W/m·K and 15 W/m·K, such as 3 W/m·K, 5 W/m·K, 7 W/m·K, 9 W/m·K, 11 W/m·K or 13 W/m·K. Moreover, the fiber-containing layer 122 has a glass transition temperature Tg greater than 120° C., preferably in the range of 120° C.-380° C., such as greater than 130° C., greater than 140° C. or greater than 150° C. In view of the foregoing, it would be understood that the metal clad substrate of the present invention has an excellent heat dissipation efficiency, and is particularly suitable for manufacturing a circuit board operating at a temperature greater than 120° C.

According to the present invention, the short fiber is in shape of a string or has an exterior appearance of a long string having a circle-like cross-section with a small diameter, and has a length of 5 µm-210 µm, such as 10 µm, 20 µm, 40 µm, 60 µm, 80 µm, 100 µm, 120 µm, 140 µm, 160 µm, 180 µm or 200 µm. In particular, the inventors found from experiments that as the length of the short fiber is in the range of 5 µm-80 µm, the metal clad substrate 10 will have a most excellent electrical insulation resistance stability. Please note that the short fiber should have a length shorter than the thickness of the fiber-containing layer 122. For example, if the thickness of the fiber-containing layer 122 is 100 µm, the length of the short fiber has to be less than 100 µm; and once the length of the short fiber is greater than 100 µm, it would be very easy for the short fiber to stick through the fiber-containing layer 122. Because the short fiber does not have a good voltage endurance, the fiber-containing layer 122 with the short fiber sticking therethrough will make the substrate have a poor voltage endurance, or even cause the metal layer 13 and the metal baseplate 11 to be electrically connected to each other via the fiber-containing layer 122. The short fiber may be selected from the group essentially consisting of short glass fiber, calcium silicate fiber, aluminum silicate fiber, carbon fiber, gypsum fiber, and any mixtures thereof. Since the short fibers are evenly dispersed in the thermally conductive bonding layer 12 and the short fibers could prevent resistance of the thermally conductive bonding layer 12 from dropping drastically at high temperature, resistance of the metal clad substrate 10 would not drop significantly at high temperature (e.g., 175° C.). As such, the metal clad substrate 10 has a quite excellent electrical insulation resistance stability, and dielectric breakdown would not occur during operation of the circuit board. In the meantime, because the length of the short fibers is micrometer-scaled and the short fibers are evenly dispersed in the thermally conductive bonding layer 12, and a large amount of heat conductive fillers are evenly dispersed in the polymer, the circuit board made from metal clad substrate of the present invention would not encounter the problem of poor heat dissipation efficiency that occurs in traditional CCL using thick thickness or large volume of glass fiber cloth. In an embodiment, the short fiber is preferably made of short glass fiber or calcium silicate fiber, the inventors found from experiments that the two types of short fiber can achieve functional effects of both an excellent electrical insulation resistance stability and a high heat dissipation efficiency at the same time.

An adhesive material used to form the upper adhesive layer 123 and/or the lower adhesive layer 121 is prepared by including plural ingredients to have a heat conductivity between 2 W/m·K and 15 W/m·K, such as 5 W/m·K, 7 W/m·K, 9 W/m·K or 12 W/m·K. The adhesive material in the form of a plate with a thickness of 100 µm has a thermal resistance below 0.5° C./W or 0.4° C./W. The adhesive material has a hardness between 65-98A, e.g., 75A, 85A or 95A, which is measured according to ASTM D2240. As such, the adhesive material has good impact resistance, and therefore it is suitable for bonding metal components. The metal components may comprise copper, aluminum, nickel, iron, tin, gold, silver or alloy thereof. In an embodiment, the strength of the adhesive material bonding to the metal component is greater than 80 kg/cm² after the adhesive material is pressed and cured. It is obvious that the addition of thermoplastic can increase adhesive strength, by which the adhesive material becomes tough but not fragile. Therefore, the adhesive material is able to be strongly and firmly adhered to metal components such as metal electrodes or substrates. The adhesive strength may be larger than 100 kg/cm² or 120 kg/cm². Preferably, the metal components include iron, aluminum, copper or alloys thereof. Preferably, the adhesive material in the form of a plate with a thickness of 100 µm is highly insulative and can withstand a voltage higher than 500 volts, e.g., 600 volts, 800 volts, 1000 volts, 1200 volts, 1400 volts, 1600 volts, 1800 volts, 2000 volts or more. In addition, the upper adhesive layer 123 and/or the lower adhesive layer 121 made from the adhesive material has a glass transition temperature Tg greater than 120° C., preferable in the range of 120° C.-380° C., such as greater than 130° C., greater than 140° C. or greater than 150° C. In other words, the upper adhesive layer 123 and/or the lower adhesive layer 121 can endure high temperature generated for high power or large current applications. Additionally, the adhesive strength between the adhesive layer and the metal components is strong, and the adhesive can endure high voltage. Accordingly, the present invention is particularly suitable for thick copper circuit applications.

To have excellent heat conductivity and electrical property and to meet the demand of required bonding strength, the lower adhesive layer 121 and the upper adhesive layer 123 are both made from an adhesive material. The adhesive material of the present application comprises a polymeric component and a large amount of heat conductive fillers. The polymeric component comprises 10%-30% by weight of the adhesive material. The heat conductive fillers are evenly dispersed in the polymeric component and comprise 70%-90% by weight of the adhesive material. In an embodiment, the polymeric component comprises thermoset epoxy resin, and a thermoplastic may be mixed with thermoset epoxy resin to enhance adhesive strength between the adhesive material and the metal material. The heat conductive filler may comprise one or more ceramic powders that can be selected from nitride, oxide or the mixture thereof. The nitride can be selected from the group consisting essentially of zirconium nitride, boron nitride, aluminum nitride, and silicon nitride. The oxide can be selected from the group consisting essentially of aluminum oxide, magnesium oxide, zinc oxide, silicon dioxide and titanium dioxide. In general, heat conductivity of oxide is relatively low, whereas the filling amount of nitride is relatively low. Therefore, oxide and nitride can be complementary to each other when they are mixed.

According to the present invention, the upper adhesive layer 123 may have a same composition as the lower adhesive layer 121. That is, they have the same ingredients, and the weight percentages of these ingredients are the same. Alternatively, the upper adhesive layer 123 may have a composition different from that of the lower adhesive layer 121. That is, they have different ingredients, or the weight percentage of these ingredients are different. Nevertheless, because both the upper adhesive layer 123 and the lower adhesive layer 121 include a polymer and a large amount of heat conductive fillers evenly dispersed in the polymer, and both are suitable for bonding metal components, the upper adhesive layer 123 and the lower adhesive layer 121 have quite similar composition even if the compositions thereof are different. The bonding property, heat conductivity and insulative property of the two adhesive layers 123 and 121 are very similar to each other.

The thermoset epoxy resin in the fiber-containing layer and/or the adhesive material can include end epoxy functional group epoxy resin, side chain epoxy functional group epoxy resin, tetra-functional group epoxy resin, other thermoset epoxy resin, or the mixture thereof. For example, the thermoset epoxy resin includes bisphenol A epoxy resin, bismaleimide, or cyanate ester.

The thermoplastic of the fiber-containing layer and/or the adhesive material may be essentially amorphous thermoplastic resin, such as phenoxy resin, polysulfone, polyethersulfone, polystyrene, polyphenylene oxide, polyphenylene sulfide, polyamide, polyimide, polyetherimide, polyetherimide/silicone block copolymer, polyurethane, polyester, polycarbonate, acrylic resin such as polymethyl methacrylate, styrene/acrylonitrile and styrene block copolymers.

The thermoset epoxy resin in the fiber-containing layer and/or the adhesive material relies on a curing agent to cure. In an embodiment, the curing agent comprises 1%-4% by weight of the fiber-containing layer and/or the adhesive material, and the curing temperature of the curing agent in the fiber-containing layer and/or the adhesive material is higher than 120° C., or preferably at about 150° C., to cure (crosslink) or catalyze to polymerize the thermoset epoxy resin. The curing agent is preferably dicyandiamide and may be used together with a curing accelerator. The commonly used curing accelerator includes urea or urea compounds, imidazole, or boron trifluoride. Moreover, the curing agent may be isophthaloyl dihydrazide, benzophenone tetracarboxylic dianhydride, diethyltoluene diamine, 3,5-dimethylthio-2,4-toluene diamine, dicyandiamide, or diaminodiphenyl sulfone (DDS). The curing agent may be substituted dicyandiamides, such as 2,6-xylenyl biguanide, solid polyamide, solid aromatic amine, solid anhydride hardener, phenolic resin hardener. For example, poly(p-hydroxy styrene), amine complex, trimethylol propane triacrylate, bismaleimides or cyanate esters may be used as the curing agent. In an embodiment, the curing agent and the curing accelerator, together with the polymeric component, comprises 15%-60% by weight of the adhesive material.

Table 1 shows thickness of thermally conductive bonding layer, bonding strength between thermally conductive bonding layer and metal material, heat conductivity, and resistance of a thermally conductive substrate of embodiments E1-E4 of the present application (which are all metal clad substrate) and comparative examples C1-C3 (which are DBC substrate, IMS, and metal clad substrate in which the thermally conductive bonding layer includes a fiber-containing layer only). All the thermally conductive substrates in E1-E4 and C1-C3 have a top-view area of 10 mm×10mm. C1 uses traditional DBS substrate, which includes a ceramic layer of 500 µm with an upper copper layer of 300 µm and a lower copper layer of 300 µm attached to upper and lower surface of the ceramic layer, respectively. C2 uses traditional IMS, which includes a thermally conductive bonding layer with an upper copper layer of 35 µm and a lower aluminum layer of 1.5 mm attached to upper and lower surface of the thermally conductive bonding layer, respectively. C3 and E1-E4 all uses a thermally conductive substrate, where an upper copper layer of 1.0 mm and a lower aluminum layer of 1.5 mm are attached to upper and lower surface of the thermally conductive bonding layer, respectively. The upper adhesive layer and lower adhesive layer in Table 1 both includes a thermoset epoxy resin comprising 14% by weight of the adhesive layer, a curing agent comprising 1% by weight of the adhesive layer, and aluminum oxide comprising 85% by weight of the adhesive layer and evenly dispersed in the thermoset epoxy resin. The fiber-containing layer includes a thermoset epoxy resin comprising 14% by weight of the fiber-containing layer, a curing agent comprising 1% by weight of the fiber-containing layer, as well as aluminum oxide comprising 79% by weight of the fiber-containing layer and short glass fiber comprising 6% by weight of the fiber-containing layer, wherein both aluminum oxide and short glass fiber are evenly dispersed in the thermoset epoxy resin. Resistance of substrate at 150° C. is measured to evaluate whether resistance of the substrate at such a high temperature drops significantly in comparison with that at room temperature of 25° C. That is, this is used to evaluate electrical insulation resistance stability of the substrate. The thermal shock test is conducted by putting substrate in an environment of -40° C. followed by 150° C. as a cycle with each temperature lasting for a duration of 30 minutes, and each cycle is repeated 500 times. After 500 times of cycles are completed, resistance of the substrate at room temperature of 25° C. is measured, so as to obtain resistance of substrate that recovers from use in an adverse environment for a long duration, thus evaluating resistance recovery of substrate. If recovered resistance of substrate drops less in comparison with initial resistance of substrate at room temperature of 25° C., it shows that resistance of substrate after thermal shock test could be retained as much as possible after a long period of time of use, revealing that the substrate has a good resistance recovery.

TABLE 1

| | Thickness of upper adhesive layer (µm) | Thickness of fiber-containing layer (µm) | Thickness of lower adhesive layer (µm) | Bonding strength (Kg/cm) | Heat conductivity (W/m·K) | Resistance @25° C. (Ω) | Resistance @150° C. (Ω) | Resistance @25° C. after thermal shock test (-40° C.~150° C., 500 cycles) (Ω) |
|---|---|---|---|---|---|---|---|---|
| C1 | Thickness of ceramic layer: 500 µm | | | >2 | 15 | 2.3×10⁹ | 6.0×10¹² | Delamination of metal layer |
| C2 | 50 | 0 | 50 | 2.9 | 8 | 4.0×10¹³ | 2.0×10⁹ | 2.5×10¹² |
| C3 | 0 | 100 | 0 | 0.8 | 3 | 5.0×10¹³ | 2.0×10¹¹ | 9.0×10¹⁰ |
| E1 | 30 | 100 | 30 | 2.5 | 5.5 | 6.0×10¹³ | 2.0×10¹¹ | 6.8×10¹² |
| E2 | 50 | 100 | 50 | 2.8 | 5.3 | 6.4×10¹³ | 2.3×10¹¹ | 6.9×10¹² |
| E3 | 75 | 100 | 75 | 2.9 | 5.2 | 7.1×10¹³ | 2.5×10¹¹ | 6.8×10¹² |
| E4 | 100 | 100 | 100 | 3.0 | 5.2 | 7.5×10¹³ | 3.0×10¹¹ | 7.0×10¹² |

As can be seen from Table 1, C1 shows that resistance of DBC substrate at high temperature of 150° C. increases in comparison with initial resistance of the DBC substrate at room temperature of 25° C., indicating that DBC substrate has an excellent electrical insulation resistance stability and a high heat conductivity in which both DBC substrate’s advantages if it is used as a thermally conductive substrate. However, although DBC substrate has a good bonding strength between the ceramic layer and the upper or lower copper layer after DBC substrate is made by cofiring, DBC substrate cannot pass the thermal shock test. Particularly, delamination between the ceramic layer and the metal material (i.e., the upper copper layer and/or the lower copper layer) occurs in the DBC substrate during the thermal shock test, and thus resistance of DBC substrate after thermal shock test cannot be measured and be obtained. Delamination problems, as said above, results from significant difference between the ceramic layer and the metal material in coefficient of thermal expansion (CTE) from each other. Therefore, traditional DBC substrate is not suitable for being used in thick copper circuit applications where the circuit is required to accommodate high power or large currents.

Also, from Table 1, C2 revels that bonding strength, heat conductivity and resistance recovery of IMS is good. However, as said above, because IMS includes a thermally conductive and electrically insulation layer, this makes resistance of IMS at high temperature of 150° C. drops drastically, and thus IMS does not have an excellent electrical insulation resistance stability. In practice, once IMS operates at a high temperature, it is very likely that dielectric breakdown problem occurs in the IMS. Therefore, traditional IMS is not suitable for being used in thick copper circuit applications where the circuit is required to accommodate high power or large currents as well.

In addition, as said above, C3 uses a metal clad substrate in which the thermally conductive bonding layer includes a fiber-containing layer only without inclusion of adhesive layer(s). Thus, from Table 1, C3 revels that bonding strength between the thermally conductive bonding layer and the upper copper layer and/or the lower aluminum layer is relatively inferior. Additionally, because the thermally conductive substrate in C3 includes a less total amount of aluminum oxide used as conductive filler, C3 has a relatively low heat conductively when compared to C1, C2 and E1-E4. In other words, C3 includes a more total amount of short fibers than C1, C2 and E1-E4, the short fibers having low heat conductivity would make the substrate of C3 has a poor heat conductivity. Nevertheless, since the thermally conductive substrate of C3 includes the fiber-containing layer, resistance of the thermally conductive substrate at high temperature of 150° C. does not drop drastically. Moreover, the inventors found that since the thermally conductive substrate of C3 does not include adhesive layer(s), and the fiber-containing layer and the metal material differs significantly in coefficient of thermal expansion (CTE) from each other, air gaps will be formed between the fiber-containing layer and the upper copper layer and/or the lower aluminum layer during thermal shock test. It can be proved from Table 1, wherein C3 shows that this results in increase of resistance of substrate and poor resistance recovery of substrate after thermal shock test.

Please further refer to Table 1. All of E1-E4 use a metal clad substrate as a thermally conductive substrate according to the present invention, in which the upper and lower adhesive layers gradually increase from 30 µm (as shown in E1) to 100 µm (as shown in E4), and the thickness of the fiber-containing layer remains at a constant value of 100 µm. Table 1 shows that all the metal clad substrates of E1-E4 have an excellent bonding strength and a superior heat conductivity. Resistance of the metal clad substrates of E1-E4 at high temperature of 150° C. does not drop drastically, and particularly, resistance of the metal clad substrates at 150° C. is at least 1×10¹⁰ Ω. Moreover, the thermal shock test shows that all the metal clad substrates of E1-E4 have an excellent resistance recovery, wherein the resistance recovery is greater than at least 1×10¹¹ Ω. For the upper or lower adhesive layer, the inventors found that if an adhesive layer has a thickness less than 30 µm, the adhesive layer will include too little amount of adhesive material, and gap-filling ability of the adhesive layer would become bad, and it is very likely to cause separation or peeling problem between the adhesive layer and the metal material. On the other hand, from Table 1, it is observed that as long as thickness of the adhesive layer is greater than 50 µm, such an adhesive layer cannot make the metal clad substrate have any noticeable and good properties. Therefore, according to the present invention, either the upper adhesive layer or the lower adhesive layer is to preferably have a thickness falling within 30 µm-50µm, such as 35 µm, 40 µm or 45 µm.

Table 2 shows thickness of thermally conductive bonding layer, bonding strength between thermally conductive bonding layer and metal material, heat conductivity, and resistance of a metal clad substrate of embodiments E5-E9 of the present invention. All the metal clad substrates in E5-E9 have a top-view area of 10 mm× 10 mm. E5-E9 all uses a metal clad substrate, where an upper copper layer of 1.0 mm and a lower aluminum layer of 1.5 mm attached to upper and lower surface of the thermally conductive bonding layer, respectively. Each of the upper adhesive layer and lower adhesive layer in Table 2 has a thickness of 50 µm. The thickness of the fiber-containing layer gradually increases from 80 µm (as shown in E5) to 180 µm (as shown in E9). The upper adhesive layer and lower adhesive layer in Table 2 both includes a thermoset epoxy resin comprising 14% by weight of the adhesive layer, a curing agent comprising 1% by weight of the adhesive layer, and aluminum oxide comprising 85% by weight of the adhesive layer and evenly dispersed in the thermoset epoxy resin. The fiber-containing layer includes a thermoset epoxy resin comprising 14% by weight of the fiber-containing layer, a curing agent comprising 1% by weight of the fiber-containing layer, as well as aluminum oxide comprising 79% by weight of the fiber-containing layer and short glass fiber comprising 6% by weight of the fiber-containing layer, wherein both aluminum oxide and short glass fiber are evenly dispersed in the thermoset epoxy resin. Likewise, resistance of substrate at 150° C. is measured to evaluate whether resistance of the substrate at such a high temperature drops significantly in comparison with that at room temperature of 25° C. That is, this is used to evaluate electrical insulation resistance stability of the substrate. The thermal shock test is also conducted by putting substrate in an environment of -40° C. followed by 150° C. as a cycle with each temperature lasting for a duration of 30 minutes, and each cycle is repeated 500 times. After 500 times of cycles are completed, resistance of the substrate at room temperature of 25° C. is measured, so as to obtain resistance of substrate that recovers from use in an adverse environment for a long duration, thus evaluating resistance recovery of substrate. If recovered resistance of substrate drops less in comparison with initial resistance of substrate at room temperature of 25° C., it shows that resistance of substrate after thermal shock test could be retained as much as possible after a long period of time of use, revealing that the substrate has a good resistance recovery.

TABLE 2

| | Thickness of upper adhesive layer (µm) | Thickness of fiber-containing layer (µm) | Thickness of lower adhesive layer (µm) | Bonding strength (Kg/cm) | Heat conductivity (W/m·K) | Resistance @25° C. (Ω) | Resistance @150° C. (Ω) | Resistance @25° C. after thermal shock test (-40° C.~150° C., 500 cycles) (Ω) |
|---|---|---|---|---|---|---|---|---|
| E5 | 50 | 80 | 50 | 2.9 | 5 | 6.2×10¹³ | 2.0×10¹¹ | 8.3×10¹² |
| E6 | 50 | 100 | 50 | 2.9 | 4.8 | 6.4×10¹³ | 2.3×10¹¹ | 8.0×10¹² |
| E7 | 50 | 120 | 50 | 2.9 | 4.3 | 6.6×10¹³ | 2.6×10¹¹ | 7.1×10¹² |
| E8 | 50 | 150 | 50 | 2.9 | 4 | 7.3×10¹³ | 3.0×10¹¹ | 8.0×10¹² |
| E9 | 50 | 180 | 50 | 2.9 | 3.7 | 7.6×10¹³ | 3.7×10¹¹ | 9.0×10¹² |

As can be seen from Table 2, as long as a metal clad substrate is used as a thermally conductive substrate, the substrate has an excellent bonding strength, a superior heat conductivity, a relatively low value of resistance of substrate at high temperature of 150° C., and a good resistance recovery. In addition, with gradual increase of thickness of fiber-containing layer, distance of heat conducting path becomes longer and the fiber-containing layer include a more total amount of short glass fiber of low heat conductivity, therefore heat conductivity of the substrate correspondingly is lowered. In order to have the substrate have a superior heat conductivity, thickness of the fiber-containing layer is preferably controlled to fall within the range of 80 µm-100µm, e.g., 85 µm, 90 µm or 95 µm.

Also, from Table 2, it is revealed that with gradual increase of thickness of fiber-containing layer, total amount of short glass fiber of low heat conductivity included in the fiber-containing is gradually increased, therefore resistance of metal clad substrate at room temperature of 25° C., resistance of metal clad substrate at high temperature of 150° C., resistance recovery of metal clad substrate are all slightly increased as thickness of the fiber-containing layer is increased. Nevertheless, such a little increase of these values does not affect bonding strength between the thermally conductive bonding layer and the metal material, and the substate still has a superior heat conductivity.

Table 3 shows thickness of thermally conductive bonding layer, resistance of metal clad substrate, and length of short fiber of embodiments E5, E10 and E11 of the present invention. All the metal clad substrates in E5, E10 and E11 have a top-view area of 10 mm×10 mm. E5, E10 and E11 all uses a metal clad substrate, where an upper copper layer of 1.0 mm and a lower aluminum layer of 1.5 mm attached to upper and lower surface of the thermally conductive bonding layer, respectively. Each of the upper adhesive layer and lower adhesive layer in Table 3 has a thickness of 50 µm. The thickness of the fiber-containing layer in all of E5, E10 and E11 is 80 µm. The upper adhesive layer and lower adhesive layer in Table 3 both includes a thermoset epoxy resin comprising 14% by weight of the adhesive layer, a curing agent comprising 1% by weight of the adhesive layer, and aluminum oxide comprising 85% by weight of the adhesive layer and evenly dispersed in the thermoset epoxy resin. The fiber-containing layer includes a thermoset epoxy resin comprising 14% by weight of the fiber-containing layer, a curing agent comprising 1% by weight of the fiber-containing layer, as well as aluminum oxide comprising 79% by weight of the fiber-containing layer and short glass fiber comprising 6% by weight of the fiber-containing layer, wherein both aluminum oxide and short glass fiber are evenly dispersed in the thermoset epoxy resin. Likewise, resistance of substrate at 150° C. is measured to evaluate whether resistance of the substrate at such a high temperature drops significantly in comparison with that at room temperature of 25° C. That is, this is used to evaluate electrical insulation resistance stability of the substrate. The short fiber in E5, E10 and E11 has different length, and thus dependency of electrical insulation resistance stability of the substrate on length of short fiber could be tested.

TABLE 3

| | Thickness of upper adhesive layer (µm) | Thickness of fiber-containing layer (µm) | Thickness of lower adhesive layer (µm) | Resistance @25° C. (Ω) | Resistance @150° C. (Ω) | Length of short fiber (µm) |
|---|---|---|---|---|---|---|
| E5 | 50 | 80 | 50 | 6.2×10¹³ | 2.0×10¹¹ | 5-80 |
| E10 | 50 | 80 | 50 | 6.2×10¹³ | 9.5×10¹⁰ | <5 |
| E11 | 50 | 80 | 50 | 6.4×10¹³ | 2.3×10¹¹ | >80 |

From Table 3, it is shown that when length of short fiber is less than 5 µm (See E10), resistance of metal clad substrate at high temperature of 150° C. is lowered. This is caused by the reason that the shorter the length of the short fiber, the more uniform the distribution of the large amount of short fibers in the fiber-containing layer, thus leading to that resistance of metal clad substrate will have a lower resistance at higher temperature.

It is found that although increase in length of short fiber may make metal clad substrate have an excellent electrical insulation resistance stability, as shown in E11, the inventors found that the short fiber may stick through the fiber-containing layer. Because the short fiber does not have a good voltage endurance, the substrate cannot endure high voltage and thus the metal layer 13 may have a likelihood to be electrically connected to the metal baseplate 11 during operation of substrate.

Moreover, it is seen from E5 in Table 3 that as length of short fiber falls within the range of 5 µm-80µm, the issue that resistance of the metal clad substrate at high temperature of 150° C. drops drastically in comparison with that at room temperature of 25° C. will not occur. The metal clad substrate can have an excellent electrical insulation resistance stability.

In practice, the metal clad substrate of the present invention has a bonding strength between the thermally conductive bonding layer and the metal layer or between the thermally conductive bonding layer and the metal baseplate in which the bonding strength ranges from 0.8 Kg/cm to 3.0 Kg/cm, e.g., 1.0 Kg/cm, 1.5 Kg/cm, 2.0 Kg/cm or 2.5 Kg/cm. Heat conductivity of the thermally conductive bonding layer could be between 2 W/m·K and 8 W/m·K, such as 3 W/m·K, 4 W/m·K, 5 W/m·K, 6 W/m·K or 7 W/m K, preferably between 3 W/m K and 6 W/m·K. The glass transition temperature Tg of the thermally conductive bonding layer is greater than 120° C., preferably in the range of 120° C.-380° C., such as greater than 130° C., greater than 140° C. or greater than 150° C. Each of the thickness of the upper adhesive layer and the lower adhesive layer could fall within the range of 30 µm-150µm, such as 40 µm, 60 µm, 80 µm, 100 µm, 120 µm or 140 µm, and preferably fall within the range of 30 µm-50µm. The fiber-containing layer could have a thickness ranging from 50 µm to 210 µm, e.g., 70 µm, 90 µm, 110 µm, 130 µm, 150 µm, 170 µm or 190 µm, and preferably have a thickness of 80 µm-100µm. The length of the short fiber could be in the range of 5 µm-210µm, such as 10 µm, 20 µm, 40 µm, 60 µm, 80 µm, 100 µm, 120 µm, 140 µm, 160 µm, 180 µm or 200 µm. In particular, as the length of the short fiber is in the range of 5 µm-80µm, the metal clad substrate will have a most excellent electrical insulation resistance stability, thus solving the problem that resistance of the thermally conductive substrate drops drastically at high temperature in comparison with that at room temperature of 25° C. Each of the metal layer and the metal baseplate could have a thickness of 0.3 mm -15 mm, such as 0.5 mm, 1 mm, 3 mm, 5 mm, 7 mm, 9 mm, 11 mm or 13 mm. According to the present invention, resistance of the metal clad substrate at 150° C. is greater than 1×10¹⁰ Ω, such as greater than 1×10¹¹ Ω or greater than 1×10¹² Ω. After a thermal shock test is conducted on the metal clad substrate of the present invention in an environment of -40° C. followed by 150° C. for 500 cycles, resistance of the metal clad substrate at room temperature of 25° C. is greater than 1×10¹¹ Ω, and particularly, greater than 1×10¹² Ω or 1×10¹³ Ω.

In summary, the present invention provides a metal clad substrate. The thermally conductive bonding layer of the metal clad substrate includes a lower adhesive layer, a fiber-containing layer, and an upper adhesive layer. Composition of the thermally conductive bonding layer is prepared and adjusted to have a superior heat conductivity. The fiber-containing layer includes a short fiber being in shape of a string and having a micrometer-scaled size, and the fiber-containing layer further includes a large amount of heat conductive fillers, wherein the short fiber and the heat conductive fillers are evenly dispersed in a polymer, such that the metal clad substrate has an excellent electrical insulation resistance stability at high temperature and, in the meanwhile, has a superior heat conductivity. Moreover, bonding strength between the upper or lower adhesive layer and the metal material is so strong that there would be no delamination problem occurring during use of the metal clad substrate. The metal clad substrate of the present invention is quite suitable for high power or large current applications using thick copper circuit, thus providing a solution to the traditional thermally conductive substrate which encounters the problems as described above.

The above-described embodiments of the present invention are intended to be illustrative only. Numerous alternative embodiments may be devised by persons skilled in the art without departing from the scope of the following claims.

What is claimed is:

1. A metal clad substrate, comprising:
a metal baseplate;
a metal layer; and
a thermally conductive bonding layer disposed between the metal baseplate and the metal layer, in which the thermally conductive bonding layer includes a lower adhesive layer, a fiber-containing layer, and an upper adhesive layer from bottom to top, an upper side and a lower side of the upper adhesive layer contacts the metal layer and the fiber-containing layer, respectively, and an upper side and a lower side of the lower adhesive layer contacts the fiber-containing layer and the metal baseplate, respectively;
wherein each of the metal layer and the metal baseplate has a thickness of 0.3 mm - 15 mm; and
wherein the fiber-containing layer includes a polymer as well as a heat conductive filler and a short fiber evenly dispersed in the polymer, and the short fiber is in shape of a string and has a length of 5 µm-210 µm.

2. The metal clad substrate of claim 1, wherein the metal layer is a copper layer, and the metal baseplate is a copper baseplate or an aluminum baseplate.

3. The metal clad substrate of claim 1, wherein the short fiber is selected from the group consisting of short glass fiber, calcium silicate fiber, aluminum silicate fiber, carbon fiber, gypsum fiber, and any mixtures thereof.

4. The metal clad substrate of claim 1, wherein the short fiber has a length shorter than a thickness of the fiber-containing layer.

5. The metal clad substrate of claim 1, wherein a length of the short fiber is in the range of 5 µm-80 µm.

6. The metal clad substrate of claim 1, wherein the polymer comprises 10-30% by weight of the fiber-containing layer and includes thermoset epoxy resin, the heat conductive fillers comprise 65-85% by weight of the fiber-containing layer, and the short fiber comprises 3-10% by weight of the fiber-containing layer; and wherein the fiber-containing layer has a thickness ranging from 50 µm to 210 µm, and the fiber-containing layer has a heat conductivity between 2 W/m·K and 15 W/m·K.

7. The metal clad substrate of claim 6, wherein the heat conductive filler comprises one or more ceramic powders that is selected from nitride, oxide, or the mixture thereof; wherein the nitride is selected from the group consisting of zirconium nitride, boron nitride, aluminum nitride, and silicon nitride; and wherein the oxide is selected from the group consisting of aluminum oxide, magnesium oxide, zinc oxide, silicon dioxide, and titanium dioxide.

8. The metal clad substrate of claim 1, wherein both the upper adhesive layer and the lower adhesive layer are made from an adhesive material, the adhesive material comprising:
a polymeric component comprising 10-30% by weight of the adhesive material, and comprising thermoset epoxy resin and thermoplastic configured to improve impact resistance of the thermoset epoxy resin; and
a heat conductive filler evenly dispersed in the polymeric component, and comprising 70-90% by weight of the adhesive material;
wherein the adhesive material has a heat conductivity between 2 W/m·K and 15 W/m·K.

9. The metal clad substrate of claim 8, wherein the heat conductive filler comprises one or more ceramic powders that is selected from nitride, oxide, or the mixture thereof; wherein the nitride is selected from the group consisting of zirconium nitride, boron nitride, aluminum nitride, and silicon nitride; and wherein the oxide is selected from the group consisting of aluminum oxide, magnesium oxide, zinc oxide, silicon dioxide, and titanium dioxide.

10. The metal clad substrate of claim 8, wherein a bonding strength between the thermally conductive bonding layer and the metal layer as well as a bonding strength between the thermally conductive bonding layer and the metal baseplate range from 0.8 Kg/cm and 3.0 Kg/cm.

11. The metal clad substrate of claim 1, wherein each of a thickness of the upper adhesive layer and a thickness of the lower adhesive layer falls within the range of 30 µm-150 µm.

12. The metal clad substrate of claim 1, wherein a resistance of the metal clad substrate at 150° C. is greater than 1×10¹⁰ Ω.

13. The metal clad substrate of claim 1, wherein after a thermal shock test is conducted on the metal clad substrate in an environment of -40° C. followed by 150° C. for 500 cycles, a resistance of the metal clad substrate at 25° C. is greater than 1×10¹¹ Ω.

14. The metal clad substrate of claim 1, wherein a glass transition temperature Tg of the thermally conductive bonding layer is in the range of 120° C.-380° C.
